(19) United States
(12) Patent Application Publication
(10) Pub. No.: US 2009/0169743 A1
(43) Pub. Date: Jul. 2, 2009

(54) Arrangement in Connection with ALD Reactor

(75) Inventors: Pekka Soininen, Helsinki (FI); Sami Sneck, Vantaa (FI)

Correspondence Address: OLIFF & BERRIDGE, PLC, P.O. BOX 320850, ALEXANDRIA, VA, 22320-4850, US

(73) Assignee: BENEQ OY, Vantaa (FI)

(21) Appl. No.: 12/083,322

(22) PCT Filed: Nov. 16, 2006
(86) PCT No.: PCT/FI2006/050499

§ 371 Date: Apr. 9, 2008

(30) Foreign Application Priority Data
Nov. 17, 2005 (FI) 20055613

(51) Int. Cl. C23C 16/44; C23C 16/54

(52) U.S. Cl. 427/255.7; 118/719

(57) ABSTRACT

The invention relates to a loading apparatus for an ALD reactor, the ALD reactor comprising a vacuum chamber (2) having a first end wall (6) and a second end wall (20), which comprises a rear flange, and side walls/casing (22) connecting the first and the second end wall, and a reaction chamber (4) provided inside the vacuum chamber (2). According to the invention, the loading apparatus is provided in the side wall/casing (22) of the vacuum chamber (2), in which case one or more substrates (10) may be introduced into the reaction chamber (4) and removed therefrom through the side wall (22) of the vacuum chamber (2).

### BACKGROUND OF THE INVENTION

The invention relates to an apparatus for loading an ALD reactor and to a method of processing a substrate in an ALD reactor. More particularly, the present invention relates to a loading apparatus for an ALD reactor according to the preamble of claim 1, the ALD reactor comprising a vacuum chamber and a reaction space provided inside the vacuum chamber. The invention further relates to a method of processing a substrate in an ALD reactor according to claim 19.

According to the prior art, the reaction chamber of an ALD reactor has been loaded by placing the substrate to be processed in a loading chamber, which is provided with a very low underpressure by suction because, conventionally, other process devices with a process pressure lower than that used in the ALD are connected to a so-called Kluster tool which comprises such a loading chamber. Such a Kluster tool arrangement is described, for example, in U.S. Pat. No. 6,902,624, FIG. 2. After this, the gate valve between the loading chamber and the reactor is opened and the base plate of the reaction chamber lowered, in which case the support pins connected to the reactor's fixed structures penetrate through the holes in the mobile substrate and are visible as in FIG. 2 of U.S. Pat. No. 6,579,374, for instance. Then transfer means supporting the substrate push it into its position on top of the support pins and the support/transfer plate of the substrate moves slightly downwards, leaving the substrate on top of the support pins. After this, they exit the ALD reactor and the gate valve is closed. Then the base plate of the reaction chamber rises, taking the substrate from top of the support pins and closing the reaction chamber. The substrate is removed in a corresponding manner.

A problem associated with the arrangement described above is that the loading of the substrate into the reaction chamber requires several matched movements of different reactor parts and integration of several devices. Furthermore, the loading chamber must be provided with a very low underpressure for the exchange of the substrate because some of the devices connected to the Kluster tool require a very low pressure. In addition, it is difficult to install the devices because the machines are serviced through the openable lid of the vacuum chamber, which makes it difficult to control the movements of the base plate of the reaction chamber. Furthermore, after underpressure has been generated by suction, the structures are subjected to a force effect (the support structures yield), which tries to change the settings of the matched movements as the reactor support structures yield.

### BRIEF DESCRIPTION OF THE INVENTION

The object of the invention is to provide a loading apparatus for an ALD reactor and a method of processing a substrate in the ALD reactor so as to solve the above-mentioned problems. The object of the invention is achieved by a loading apparatus according to the characterizing part of claim 1, which is characterized in that it comprises a loading apparatus arranged in a first or a second end wall or a side wall/casing of the vacuum chamber so that one or more substrates may be introduced into the reaction space inside the vacuum chamber and removed therefrom by one linear movement. The object of the invention is further achieved by a method according to the characterizing part of claim 19, which is characterized in that the method comprises the following steps: placing one or more substrates in a loading chamber outside a vacuum chamber; generating underpressure corresponding to the underpressure in the vacuum chamber of the ALD reactor in the loading chamber; opening a gate valve, introducing the substrate into the reaction space inside the vacuum chamber by one linear movement; performing the processing and removing the substrate from the reaction space; closing the gate valve; pressurizing the loading chamber to the atmospheric pressure and removing the substrate from the loading chamber.

Preferred embodiments of the invention are disclosed in the dependent claims.

The invention is based on the fact that an ALD reactor is not loaded through an openable base plate of the reaction chamber but by one linear loading movement directly into the reactor space, in which case loading and unloading are performed by one linear movement into the reactor space. In that case, a separate reaction chamber is used in the vacuum chamber, the reaction chamber comprising an openable wall and a loading opening arranged in the side wall/casing or one end wall of the vacuum chamber of the ALD reactor. This is achieved by providing the side wall of the vacuum chamber or the cylindrical casing of the vacuum chamber or one of the end walls with a loading opening, to which loading means may be connected or integrated. Furthermore, the reaction chamber arranged inside the vacuum chamber is provided with an openable and closable wall, through which a substrate may be loaded into the reaction chamber. The loading opening is preferably aligned with the openable side wall of the reaction chamber so that loading means can load the substrate into the reaction chamber of the reactor by one linear movement, and thus the substrate is introduced directly into the reaction chamber through the loading opening of the vacuum chamber and the openable side wall of the reaction chamber. According to another embodiment, the vacuum chamber does not need to include a separate reaction chamber but the inner space of the vacuum chamber or part of it may be used as the reaction space. In other words, it is essential to the invention that an ALD reactor is provided with loading means that enable loading of the substrate into the reaction space in the vacuum chamber and removal therefrom by one linear movement.

An advantage of the method and system according to the invention is that, compared to the loading of a prior art reactor, cross-movements between mobile reactor parts can be eliminated and the loading and unloading performed by one linear movement. Thus movements that need to be synchronized and matched can be avoided, the structure of the ALD can be made simpler, and the loading and unloading can even be performed manually. Furthermore, since the loading means are designed to serve exclusively the ALD reactor, the underpressure used in the loading chamber of the loading means may be the same as the pressure used in the vacuum chamber of the ALD reactor, and the vacuum chamber does not need to be provided with a very low underpressure usually employed in the loading chamber during loading in the prior art. As a result of this, the pressure in the ALD reactor may be maintained constant during the loading and unloading, and no turbo pump or the like is needed. In that case, fixed sources can be kept behind diffusion seals and they require no separate shut-off valves, which enables full-glass constructions of source pipes and higher source temperatures.

### BRIEF DESCRIPTION OF THE FIGURES

The invention will now be described in greater detail by means of preferred embodiments with reference to the accompanying drawings, in which

FIG. 1 illustrates an ALD reactor and its loading apparatus according to an embodiment of the present invention when a substrate is in a loading chamber; and

FIG. 2 illustrates the ALD reactor and its loading device according to FIG. 1 when a substrate has been loaded into a reaction chamber.

### DETAILED DESCRIPTION OF THE INVENTION

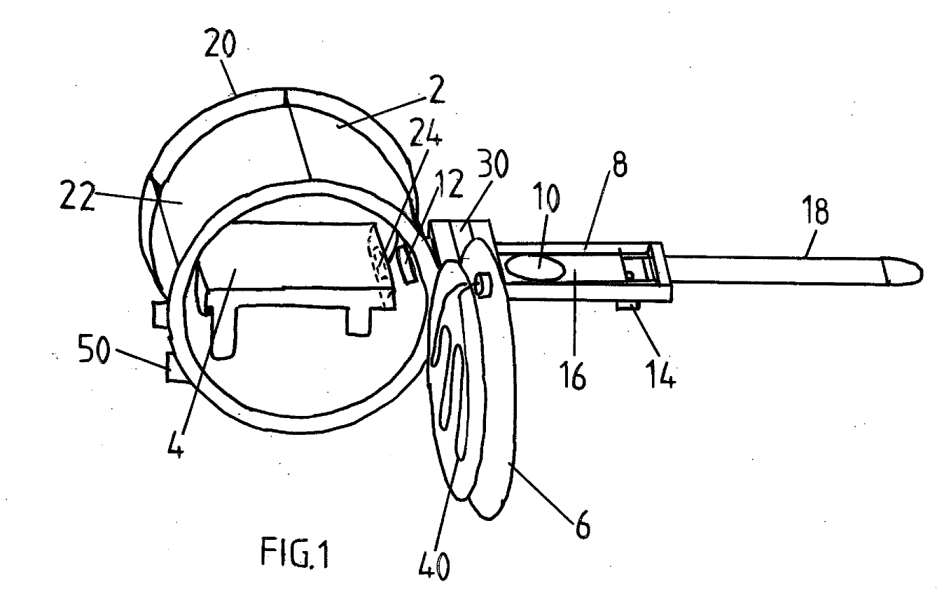

FIG. 1 illustrates an embodiment of an ALD reactor and its loading apparatus according to the present invention. Such an ALD reactor comprises a vacuum chamber 2 having a first end wall 6 and a second end wall 20. The first end wall 6 comprises a conventional loading hatch which, according to the invention, is not used for loading a substrate into the ALD reactor but for maintenance and service. In this embodiment, the first end wall is further provided with a thermal resistance 40 for heating the ALD reactor to a desired temperature The second end wall 20 forms a rear flange for the vacuum chamber. The vacuum chamber 2 further comprises side walls 22, which connect the first and the second end wall 6, 20 and extend between them and which, in the case of the cylindrical vacuum chamber of FIG. 1, form a casing 22. Furthermore, two source material pipes are connected to the casing 22 of the vacuum chamber 2 for feeding one or more reaction gases into the reaction chamber 4.

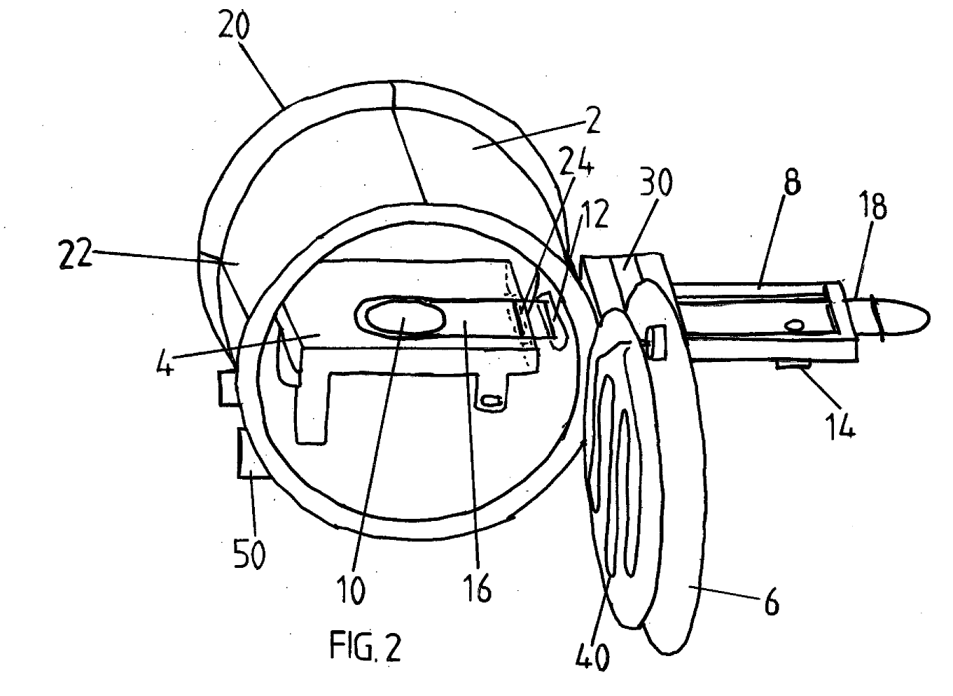

In accordance with FIGS. 1 and 2, a reaction chamber 4 is provided inside the vacuum chamber 2, the source material pipes 50 being connected to the reaction chamber. The substrate to be processed during an ALD process is placed inside this reaction chamber 4. Furthermore, in accordance with FIGS. 1 and 2, the reaction chamber 4 comprises a cover plate and a base plate, which may be attached to each other or made of a single piece and which form a top and a bottom wall of the reaction chamber 4, the walls being substantially in the horizontal plane. Substantially perpendicular side walls extend between the top wall and the bottom wall. The top wall, bottom wall and side walls define the inner space of the reaction chamber where the substrate is placed for processing. For introducing the substrate into the reaction chamber, the reaction chamber 4 comprises an openable and closable side wall 24, through which the substrate may be introduced into the reaction chamber.

According to FIG. 1, the casing 22 of the vacuum chamber 2 is provided with a loading opening 12, through which the substrate may be introduced into the vacuum chamber 2 and further through the openable side wall 24 of the reaction chamber 4 into the reaction chamber 4. Loading means have been integrated into or otherwise functionally connected to the loading opening in the casing 22 of the vacuum chamber 2. These loading means comprise a loading chamber 8, which is provided with a holder 16 for receiving the substrate 10. There may be one or more holders 16 and each of them may be arranged to receive one or more substrates 10, which, in FIGS. 1 and 2, is a silicon disc. The holder 16 may also function as a holder or base for the substrate in the reaction chamber 4, in which case there is no need to move the substrate 10 onto a separate base plate when it is introduced into the reaction chamber 4.

Pressurizing means 14 are connected to the loading chamber 8 for generating underpressure in the loading chamber 8. These pressurizing means 14 may comprise a pump (not shown), which generates underpressure in the loading chamber 8 through suction. In the embodiment according to the invention, the underpressure to be generated in the loading chamber 8 is preferably the same as the underpressure of the vacuum chamber 2. Between the loading chamber 8 and the vacuum chamber, there are valve means 30, such as a gate valve for separating the loading chamber 8 and the vacuum chamber 2 and for connecting them for introducing the substrate 10 into the reaction chamber 4. In the embodiment according to FIGS. 1 and 2, the loading means further comprise a loading arm 18, which is connected to the holder 16 so that the holder 16 can be moved inside the reaction chamber through the loading opening 12 and the openable side wall 24 of the reaction chamber 4 by moving the transfer arm 18. In this embodiment, the loading arm is operated manually but electric and/or otherwise automated transfer means for moving the substrate into the reaction chamber 4 may also be connected to the holder 16. The feed movement may also be implemented by a magnetic coupling, in which case a rod inside a feed pipe is moved by a magnet outside the feed pipe. In that case, the linear movement does not need to be performed through the wall of the loading chamber. It is essential to the invention that the loading apparatus is formed in, connected to or integrated into the side wall/casing 22 of the vacuum chamber 2 and/or the loading opening 12 provided therein, in which case one or more substrates 10 may be introduced into the reaction chamber 4 and removed therefrom through the side wall 22 of the vacuum chamber 2. In that case, one or more substrates 10 may be introduced into the reaction chamber 4 and removed therefrom through the loading opening 12 arranged in the side wall 22 of the vacuum chamber 2 and the openable side wall 24 arranged in the reaction chamber 4 by loading means. To allow efficient performance, the loading opening 12 is aligned with the openable side wall of the reaction chamber 4 so that the substrate 10 can be introduced into the reaction chamber 4 and removed therefrom by one linear movement. The introduction of the substrate into the reaction chamber 4 will be described in greater detail below.

In the simplest embodiment, the side wall is integrated into the transfer device, in which case it closes the side wall for the duration of processing. In that case, the arm is fixed to the side wall during the processing or it may be removed from the side wall by means of a thread, for example, to prevent thermal losses. The loading apparatus may also be manufactured so that it comprises actuating means for opening and closing the openable side wall 24 of the reaction chamber 4. These actuating means may be separate, in which case they can be controlled regardless of the loading of the substrate 10 into the reaction chamber. However, the actuating means are preferably functionally connected to the loading means for integrating the opening and closing of the openable side wall 24 of the reaction chamber 4 into the introduction of the substrate 10 into the reaction chamber 4 and its removal therefrom by the loading means. In that case, the openable side wall of the reaction chamber 4 is arranged to be closable when the holder 16 of the substrate 10 is inside the reaction chamber 4 and when the transfer arm 18 and/or the holder 16 is not inside the reaction chamber 4. In other words, the actuating means are arranged to open the openable side wall when the substrate is introduced and removed and to close the openable side wall when the substrate is inside the reaction chamber 4 or outside of it.

In FIG. 1, the substrate 10 is arranged in the holder 16 in the loading chamber 8 for introducing it into the reaction chamber 4. Underpressure that substantially corresponds to the underpressure of the vacuum chamber 2 is generated in the loading chamber 8 by pressurizing means 14. After this, the gate valve 30 is opened. The gate valve may typically be controlled separately either manually or by actuating means. The gate valve may also be opened employing the movement of the loading arm. In that case, the moving of the loading arm opens the gate valve 30, which is arranged in connection with the loading opening 12 arranged in the casing 22 of the vacuum chamber 2. A connection is thus formed between the loading chamber 8 and the vacuum chamber 2 for introducing the substrate 10 and the holder 16 and/or the loading arm 18 into the vacuum chamber. The operation of the gate valve 30 may be connected to the movement of the loading arm 18 and/or the holder 16, in which case the gate valve 30 opens when the loading arm 18 starts to move the substrate towards the reaction chamber. Alternatively, the gate valve 30 may be opened by separate control means regardless of the movement of the loading arm 18 or other transfer means.

After the gate valve 30 has opened, the substrate 10 is introduced linearly forwards toward the reaction chamber 4 through the loading opening 12 in the casing 22 of the vacuum chamber 2. In the most preferred embodiment, the side wall 24 of the reaction chamber is integrated into the holder 16. In that case, the side wall 24 of the reaction chamber closes as the linear movement ends, thus forming a uniform reaction space.

In FIG. 2, the substrate 10 is illustrated inside the reaction chamber 4, in which case the loading arm 18 is fully extended inside the chamber. The substrate 10 is removed from the chamber in a corresponding manner but in a reverse order. In other words, after the substrate has been processed, the loading arm 18 is withdrawn from the reactor, in which case the side wall 24 of the reaction chamber opens. The loading arm 18 is withdrawn until it reaches the initial situation according to FIG. 1, the gate valve 30 is closed and the loading chamber 8 is pressurized back to the atmospheric pressure.

It is clear to a person skilled in the art that the loading means may be provided in any wall of the vacuum chamber and also arranged so that loading takes place in the lateral direction, from the bottom, from the top or in a diagonal direction. Furthermore, the holders of the loading means may be formed so that the substrates may be placed in them and taken into the reaction space in a horizontal position, vertical position or in any position between these.

Furthermore, the loading means, such as the loading arm or the holder, may be provided with a wall portion which forms part of the wall of the reaction space, closing the reaction space when the substrate is inside the reaction space. In that case, this wall portion may form part of the openable wall of the reaction chamber 4, for example, in which case the reaction space is closed and sealed automatically when the loading means and the substrate are introduced into the reaction chamber. In that case, the loading arm is left in the loading position until the substrate is removed from the reaction space.

By means of the apparatus and method described above, a substrate may be loaded into the reaction chamber and removed therefrom by a simple linear movement, in which case the reactor structure may be implemented in the simplest possible manner. To achieve this, the loading means are formed so that the holder, which receives the substrate, can be moved directly into the reactor space by one linear movement so that the loading of the reactor does not require matching of several movements.

It is clear to a person skilled in the art that the reactor may also be used in other growing processes of a thin film, such as in CVD processing devices.

It will be obvious to a person skilled in the art that, as the technology advances, the inventive concepts may be implemented in various ways. The invention and its embodiments are thus not limited to the examples described above but may vary within the scope of the claims.

1-22. (canceled)

23. An ALD reactor comprising a vacuum chamber and a reaction chamber arranged inside the vacuum chamber wherein the ALD reactor comprises a loading apparatus which is arranged in a first or a second end wall or a side wall/casing of the vacuum chamber so that one or more substrates may be introduced into the reaction chamber inside the vacuum chamber and correspondingly removed therefrom by one linear movement.

24. An ALD reactor according to claim 23, wherein the ALD reactor comprises a loading opening formed in the side wall/casing or in the first or the second end wall of the vacuum chamber, the loading apparatus being connected to or integrated into the loading opening.

25. An ALD reactor according to claim 24, wherein the loading apparatus comprises loading means for moving one or more substrates into the reaction space through the loading opening.

26. A loading apparatus according to claim 25, wherein the loading means comprise a loading chamber where the substrate may be placed for feeding it into the reaction chamber.

27. An ALD reactor according to claim 25, wherein the loading means comprise one or more holders for receiving one or more substrates.

28. An ALD reactor according to claim 27, wherein the holder is also arranged to function as the substrate holder during the processing in the reaction chamber.

29. An ALD reactor according to claim 25, wherein the loading means further comprise pressurizing means for providing underpressure in the loading chamber.

30. An ALD reactor according to claim 25, wherein the loading means further comprise transfer means for moving one or more substrates placed in the holder into the reaction chamber and for removing them therefrom.

31. An ALD reactor according to claim 30, wherein the transfer means have been implemented as a manually operated loading arm, which is connected to one or more substrate holders for introducing the substrate into the reaction chamber and for removing it therefrom.

32. An ALD reactor according to claim 30, wherein the transfer means have been implemented as electrically operated means.

33. An ALD reactor according to claim 25, wherein the loading apparatus further comprises valve means arranged between the vacuum chamber and the loading chamber.

34. An ALD reactor according to claim 23, wherein the separate the reaction chamber comprises a reaction space into which one or more substrates may be introduced and removed therefrom by one linear movement.

35. An ALD reactor according to claim 34, wherein the reaction chamber is provided with an openable wall and loading means for introducing one or more substrates into the reaction chamber through a loading opening in the side wall of the vacuum chamber and the openable wall of the reaction chamber and for removing them therefrom.

36. An ALD reactor according to claim 35, wherein the loading opening is aligned with the openable wall of the reaction chamber so that the substrate may be introduced into the reaction chamber and removed therefrom by one linear movement.

37. An ALD reactor according to claim 35, wherein the ALD reactor further comprises actuating means for opening and closing the openable wall of the reaction chamber.

38. An ALD reactor according to claim 37, wherein the actuating means are functionally connected to the loading means for integrating the opening and closing of the openable wall of the reaction chamber into the introduction of the substrate into the reaction chamber and its removal therefrom by the loading means.

39. An ALD reactor according to claim 35, wherein the loading means comprise a wall portion which forms at least part of the openable wall of the reaction chamber when the substrate is inside the reaction space.

40. A method of processing a substrate in an ALD reactor, the method comprises the following steps:
placing one or more substrates in a loading chamber outside a vacuum chamber;
generating underpressure corresponding to the underpressure of the vacuum chamber of the ALD reactor in the loading chamber;
introducing the substrate into a separate reaction chamber inside the vacuum chamber by one linear movement;
processing the substrate; and
removing the substrate from the reaction chamber and vacuum chamber back to the loading chamber.

41. A method according to claim 40, wherein the method further comprises heating the substrate to a desired temperature after the substrate has been introduced into the reaction space and then processing the substrate by an ALD process.

42. A method according to claim 40, wherein the opening and closing of the reaction chamber is combined with the steps of introducing the substrate into and removing it from the reaction chamber.

43. A method according to claim 40, wherein the steps for introducing the substrate into the reaction chamber and for removing it from the reaction chamber are performed manually.

44. A method according to claim 40, wherein the steps of introducing the substrate into the reaction chamber and for removing it from the reaction chamber are automated.
